(19) United States
(12) Patent Application Publication
(10) Pub. No.: US 2025/0338579 A1
(43) Pub. Date: Oct. 30, 2025

(54) SEMICONDUCTOR DEVICE

(71) Applicant: Samsung Electronics Co., Ltd., Suwon-si (KR)

(72) Inventors: Inhae ZOH, Suwon-si (KR); Soomin SON, Suwon-si (KR); Suk YANG, Suwon-si (KR); Sangmoon LEE, Suwon-si (KR); Soobin HAN, Suwon-si (KR)

(73) Assignee: Samsung Electronics Co., Ltd., Suwon-si (KR)

(21) Appl. No.: 18/916,975

(22) Filed: Oct. 16, 2024

(30) Foreign Application Priority Data
Apr. 30, 2024 (KR) 10-2024-0057795

(51) Int. Cl. H01L 29/08; H01L 21/8234; H01L 27/088; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/018; H10D 84/013; H10D 84/0135; H10D 84/038; H10D 84/83

(57) ABSTRACT

A semiconductor device may include a substrate including an active pattern, first channel layers spaced apart on the active pattern in a vertical direction, a first gate structure surrounding the first channel layers, first source/drain patterns on both sides of the first gate structure and connected to the first channel layers, first internal spacers between the first gate structure and the first source/drain patterns, second channel layers spaced apart in the vertical direction on the first channel layers, a second gate structure on the first gate structure and surrounding the second channel layers, second source/drain patterns on both sides of the second gate structure and connected to the second channel layers, and second internal spacers between the second gate structure and the second source/drain patterns. The first and second internal spacers may have different shapes. The vertical direction may be perpendicular to an upper surface of the substrate.

### CROSS-REFERENCE TO RELATED APPLICATION(S)

This application claims the benefit under 35 USC 119(a) of Korean Patent Application No. 10-2024-0057795 filed on Apr. 30, 2024 in the Korean Intellectual Property Office, the entire disclosure of which is incorporated herein by reference for all purposes.

### BACKGROUND

Inventive concepts relate to a semiconductor device and a method of manufacturing the same.

As the demand for high performance, speed, and/or multifunctionality in semiconductor devices increases, the degree of integration of semiconductor devices is increasing. In order to reduce limitations in operating characteristics due to size reduction of planar metal oxide semiconductor (MOSFET), efforts are being undertaken to develop semiconductor devices including FinFET with a fin-shaped channel, and Gate-All-Around type field effect transistor including nanosheets surrounded by a gate.

### SUMMARY

Example embodiments provide a semiconductor device having improved electrical characteristics and reliability.

According to an example embodiment, a semiconductor device may include a substrate including an active pattern; first channel layers spaced apart from each other on the active pattern in a vertical direction, the vertical direction being perpendicular to an upper surface of the substrate; a first gate structure surrounding the first channel layers; first source/drain patterns on both sides of the first gate structure and connected to the first channel layers; first internal spacers between the first gate structure and the first source/drain patterns; second channel layers spaced apart from each other in the vertical direction on the first channel layers; a second gate structure on the first gate structure and surrounding the second channel layers; second source/drain patterns on both sides of the second gate structure and connected to the second channel layers; and second internal spacers between the second gate structure and the second source/drain patterns, a shape of the second internal spacers being different from a shape of the first internal spacers.

According to an example embodiment, a semiconductor device may include a substrate including an active pattern; first channel layers spaced apart from each other on the active pattern in a vertical direction, the vertical direction being perpendicular to an upper surface of the substrate; a first gate structure surrounding the first channel layers; first source/drain patterns on both sides of the first gate structure and connected to the first channel layers; first internal spacers between the first gate structure and the first source/drain patterns, concave side surfaces of the first internal spacers being in contact with the first gate structure; second channel layers spaced apart from each other in the vertical direction on the first channel layers; a second gate structure surrounding the second channel layers on the first gate structure; second source/drain patterns on both sides of the second gate structure and connected to the second channel layers; and second internal spacers between the second gate structure and the second source/drain patterns, each of the second internal spacers including a first spacer portion in contact with the second source/drain patterns and a second spacer portion in contact with the second gate structure.

According to an example embodiment, a semiconductor device may include a substrate including an active pattern; first channel layers spaced apart from each other on the active pattern in a vertical direction, perpendicular to an upper surface of the substrate; a first gate structure surrounding the first channel layers; first source/drain patterns on both sides of the first gate structure, the first source/drain patterns being connected to the first channel layers, the first source/drain patterns including indented portions, and the indented portions of the first source/drain patterns being indented toward portions of the first gate structure; second channel layers spaced apart from each other in the vertical direction on the first channel layers; a second gate structure surrounding the second channel layers on the first gate structure; second source/drain patterns on both sides of the second gate structure and connected to the second channel layers; and internal spacers between the second gate structure and the second source/drain patterns.

### BRIEF DESCRIPTION OF DRAWINGS

The above and other aspects, features, and advantages of inventive concepts will be more clearly understood from the following detailed description, taken in conjunction with the accompanying drawings, in which:

FIG. 1 is a plan view illustrating a semiconductor device according to an example embodiment;

FIG. 2 is a cross-sectional view of the semiconductor device of FIG. 1 taken along line I1-I1′;

FIGS. 3A and 3B are cross-sectional views of the semiconductor device of FIG. 1 taken along lines II1-II1′ and II2-II2′, respectively;

FIGS. 4A and 4B are partially enlarged views illustrating “A1” and “B1” of the semiconductor device of FIG. 2, respectively;

FIG. 5 is a cross-sectional view illustrating a semiconductor device according to an example embodiment;

FIGS. 6A and 6B are partially enlarged views illustrating “A2” and “B2” of the semiconductor device of FIG. 5, respectively;

FIG. 7 is a cross-sectional view illustrating a semiconductor device according to an example embodiment;

FIG. 8 is a plan view illustrating a semiconductor device according to an example embodiment;

FIG. 9 is a cross-sectional view of the semiconductor device of FIG. 8 taken along line I2-I2′;

FIGS. 10A and 10B are partially enlarged views illustrating “A3” and “B3” of the semiconductor device of FIG. 9, respectively;

FIGS. 11A to 11H are cross-sectional views for each major process to illustrate part (formation of first and second source/drain patterns) of a semiconductor device manufacturing method according to an example embodiment;

FIG. 12A is a schematic diagram illustrating a process of growing a first source/drain pattern in the process of FIG. 11E, and FIG. 12B is a schematic diagram illustrating a process of growing a second source/drain pattern in the process of FIG. 11H; and

FIGS. 13A to 13D are cross-sectional views of respective main processes for describing another part (formation of first and second gate structures) of the semiconductor device manufacturing method according to an example embodiment.

### DETAILED DESCRIPTION

Hereinafter, example embodiments will be described with reference to the accompanying drawings.

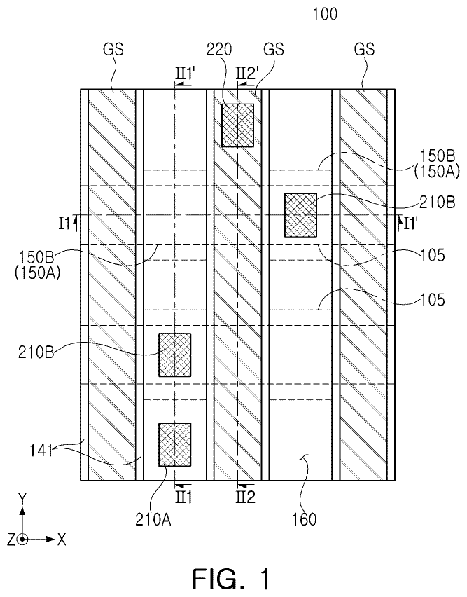

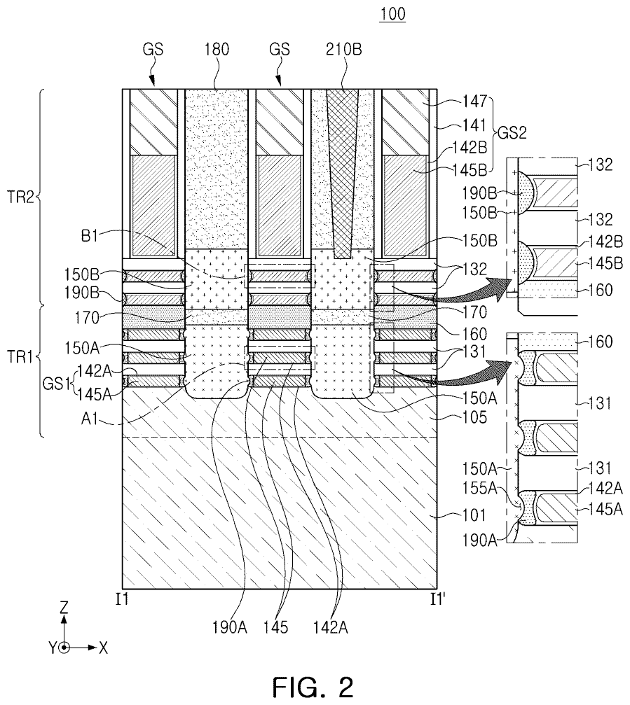

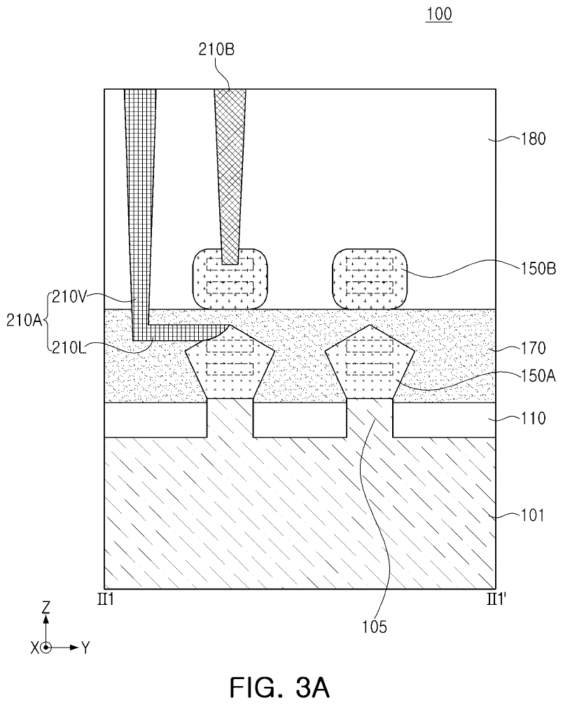

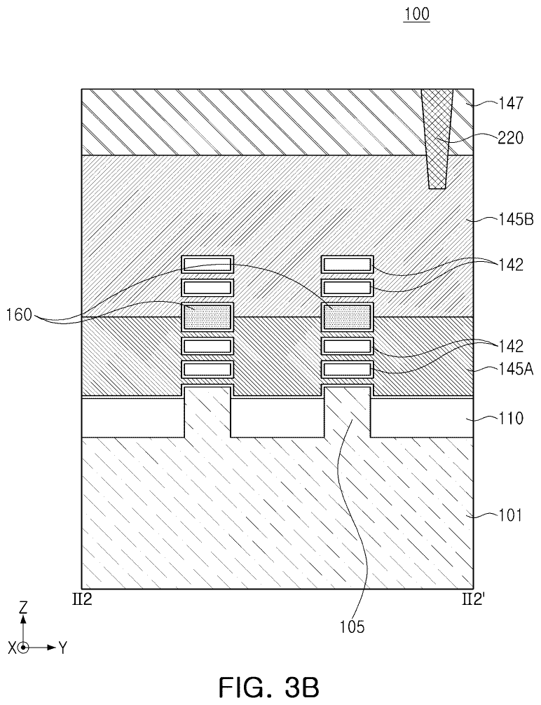

FIG. 1 is a plan view illustrating a semiconductor device according to an example embodiment, FIG. 2 is a cross-sectional view of the semiconductor device of FIG. 1 taken along line I1-I1′, and FIGS. 3A and 3B are cross-sectional views of the semiconductor device of FIG. 1 taken along lines II1-II1′ and II2-II2′, respectively.

Referring to FIGS. 1, 2, 3A, and 3B, a semiconductor device 100 includes active patterns 105 extending in a first direction (for example, X-direction) on the substrate 101, first channel layers 131 (also referred to as “lower channel layers”) spaced apart from each other in a direction perpendicular to the upper surface of the substrate 101 (for example, Z-direction) on the areas of the active patterns 105, second channel layers 132 (also referred to as “upper channel layers”) spaced apart from each other in the vertical direction (for example, Z-direction) on the first channel layers 131, and gate structures (GS) extending across the regions of the active patterns 105 in a second direction (for example, Z-direction) intersecting the first direction (for example, X-direction), and surrounding the first channel layers 131 and the second channel layers 132.

Referring to FIG. 1, FIG. 1 shows the active patterns 105 include two active patterns, and the gate structures GS include three gate structures crossing the regions of the two active patterns 105, but inventive concepts are not limited thereto.

The substrate 101 may include a semiconductor material, for example, a group IV semiconductor, a group III-V compound semiconductor, or a group II-VI compound semiconductor. For example, the group IV semiconductor may include silicon (Si), germanium (Ge), or silicon germanium (SiGe). The substrate 101 may include a bulk wafer, an epitaxial layer, or a silicon on insulator (SOI) layer.

As illustrated in FIG. 1, the active pattern 105 may have a fin-shaped structure extending from the substrate 101 in a first direction (for example, X-direction). As illustrated in FIGS. 3A and 3B, the device isolation layer 110 may define an active pattern 105 in the substrate 101. The device isolation layer 110 is disposed on the substrate 101, and a portion of the active pattern 105 may protrude from the upper surface of the device isolation layer 110. For example, the device isolation layer 110 may be formed through a shallow trench isolation (STI) process. The device isolation layer 110 may include an insulating material. For example, the device isolation layer 110 may include, for example, silicon oxide, silicon nitride, silicon oxynitride, or a combination thereof.

As illustrated in FIG. 2, the semiconductor device 100 according to the present embodiment may include a first transistor TR1 and a second transistor TR2 stacked on each of the regions of the active patterns 105. Each of the first and second transistors TR1 and TR2 employed in the present embodiment may be a Multi Bridge Channel FET (MBCFET™) that includes a gate structure (GS) surrounding the first and second channel layers 131 and 132 disposed on the active pattern 105. The gate structure GS employed in the present embodiment includes the first gate structure GS1 of the first transistor TR1 and the second gate structure GS2 of the second transistor TR2.

In detail, referring to FIGS. 2, 3A, and 3B, the first transistor structure TR1 may include first channel layers 131 stacked on the active pattern 105, a first gate electrode 145A surrounding the first channel layers 131, first source/drain patterns 150A (also referred to as “lower source/drain patterns”) connected to the first channel layers 131 on one side surface of the first gate electrode 145A, and a first gate insulating layer 142A between the first channel layers 131 and the first gate electrode 145A.

Similarly, the second transistor structure TR2 may include second channel layers 132 (also referred to as “upper channel layer”), a second gate electrode 145B surrounding the second channel layers 132, second source/drain patterns 150B (also referred to as “upper source/drain patterns”) connected to the second channel layers 132 on both sides of the second gate electrode 145B, and a second gate insulating layer 142B between the second channel layers 132 and the second gate electrode 145B.

The semiconductor device 100 according to the present embodiment may include an isolating insulation layer 170 disposed on the first source/drain patterns 150A to electrically separate the first source/drain patterns 150A and the second source/drain patterns 150B from each other. The isolating insulation layer 170 employed in the present embodiment may provide a separation structure that stably covers both edge areas in the first direction (for example, X-direction) from the upper surface of the first source/drain patterns 150A.

As described above, the first channel layers 131 are stacked on one area of the active pattern 105 while being spaced apart from each other in the vertical direction (for example, Z-direction). The first channel layers 131 may be provided in plural numbers (for example, two or three), and each includes a semiconductor pattern. For example, the first channel layers 131 may include at least one of silicon (Si), silicon germanium (SiGe), and germanium (Ge). Similarly, the second channel layers 132 may be provided in plural numbers (for example, two or three), and each may include a semiconductor pattern. For example, the second channel layers 132 may include at least one of silicon (Si), silicon germanium (SiGe), and germanium (Ge).

An intermediate insulating pattern 160 is disposed on the uppermost first channel layer among the first channel layers 131, and the second channel layers 132 are stacked on the intermediate insulating pattern 160 while being spaced apart from each other in a vertical direction (for example, Z-direction). The intermediate insulating pattern 160 may be arranged to overlap the first channel layers 131 and the second channel layers 132 in a direction perpendicular to the first channel layers 131 and the second channel layers 132 (for example, Z-direction). In this way, the stacked first channel layers 131 and the stacked second channel layers 132 may be separated by the intermediate insulating pattern 160.

The intermediate insulating pattern 160 includes an insulating material and may include, for example, at least one of silicon nitride, silicon oxynitride, or silicon carbonitride. The intermediate insulating pattern 160 may be a single insulating material layer, but in some embodiments, it may include multiple insulating material layers.

Referring to FIGS. 2 and 3B, the first gate insulating layer 142A may be disposed not only between the first channel layers 131 and the first gate electrode 145A, but also on the lower surface and some side surfaces of the intermediate insulating pattern 160. Additionally, the first gate insulating layer 142A may extend on the device isolation layer 110. The second gate insulating layer 142B may be disposed between the second channel layers 132 and the second gate electrode 145A and on the upper surface and some side surfaces of the intermediate insulating pattern 160.

The gate structure GS may further include gate spacers 141. Gate spacers 141 may be disposed on both side walls of the electrode portion extending in the second direction (for example, Y-direction) on the uppermost second channel layers 132 of the second gate electrode 145B. A gate capping layer 147 may be formed on a portion of the second gate electrode 145B between the gate spacers 141.

The first gate electrode 145A and the second gate electrode 145B used in the present embodiment may include conductive materials having different work functions. For example, the first and second gate electrodes 145A and 145B may include at least one of W, Ti, Ta, Mo, TiN, TaN, WN, TiON, TiAlC, TiAlN, and TaAlC. The first and second gate electrodes 145A and 145B may include a semiconductor material such as doped polysilicon. The first and second gate electrodes 145A and 145B may each be composed of two or more multiple layers.

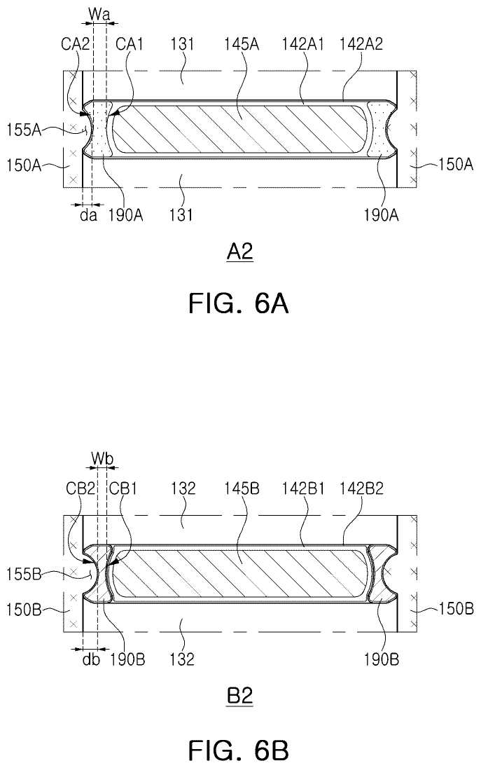

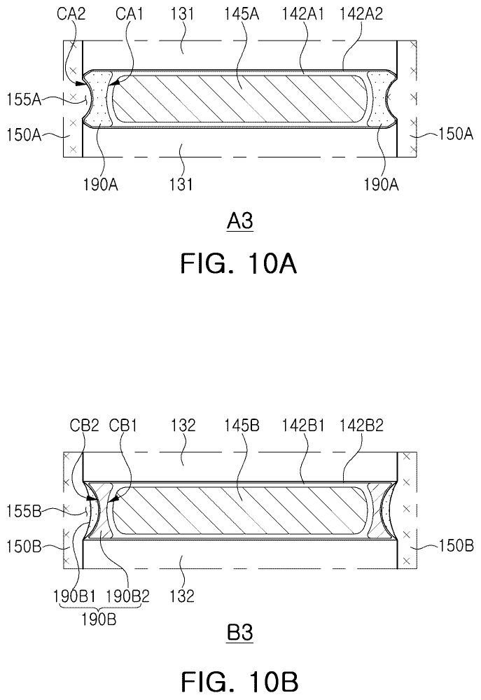

The first and second gate insulating layers 142A and 142B may each include oxide, nitride, and/or a high-k material. The first and second gate insulating layers 142A and 142B may be composed of different dielectric layers. The high dielectric constant material refers to a dielectric material having a higher dielectric constant than a silicon oxide film (SiO₂), and the high dielectric constant material may include at least one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some embodiments, each of the first and second gate insulating layers 142A and 142B may include an interface insulating film and a high-κ dielectric film (see FIGS. 6A and 6B and 10A and 10B).

For example, the gate spacers 141 may include at least one of silicon nitride and silicon oxynitride. In some embodiments, the gate spacers 141 may include a multilayer structure. The gate capping layer 147 may include, for example, silicon nitride, silicon oxynitride, silicon carbonitride, or silicon oxycarbonitride.

In some embodiments, the first and second transistors TR1 and TR2 may share a single gate structure GS. For example, a single gate structure may be provided as a common gate electrode surrounding the first and second channel layers 131 and 132.

The first source/drain pattern 150A may be disposed in the recessed portion of the active pattern 105 on both sides of the first channel layers 131. The first source/drain pattern 150A may be provided as the source region or drain region of the first transistor TR1. The first source/drain pattern 150A may include epitaxial growth from both sides of the surface of the recessed portion of the active pattern 105 and the first channel layer 131. Similarly, the second source/drain patterns 150B are disposed on both sides of the second channel layers 132 and may serve as the source region or drain region of the second transistor TR2. The second source/drain pattern 150B may include epitaxial growth using both sides of the second channel layer 132 as a seed layer.

The first and second source/drain patterns 150A and 150B may include a semiconductor epitaxial such as silicon (Si). The first and second source/drain patterns 150A and 150B may include impurities of different types and/or concentrations. For example, when the first transistor TR1 is a P-type MOSFET, the first source/drain patterns 150A may include silicon germanium (SiGe) doped with a p-type impurity, and when the second transistor TR2 is an N-type MOSFET, the second source/drain patterns 150B may include silicon (Si) doped with an n-type impurity. In detail, in the first transistor TR1, the first source/drain patterns 150A formed of silicon germanium (SiGe) act as a stressor that applies compressive force to the first channel layers 131, thereby increasing charge mobility within the first channel layers 131.

In some embodiments, cross-sections of the first and second source/drain patterns 150A and 150B along the second direction (for example, Y-direction) may have different shapes. For example, the cross-section of the first source/drain patterns 150A may have a pentagonal shape, and the cross-section of the second source/drain patterns 150B may have a polygonal shape with gentle angles (see FIG. 3).

Referring to FIGS. 3A and 3B, the first and second transistors TR1 and TR2 may include first and second internal spacers 190A and 190B, respectively. The first internal spacer 190A may be disposed between the first gate structure GS1 (in detail, portions adjacent to the first channel layers 131) and the first source/drain patterns 150A, and the second internal spacers 190B may be disposed between the second gate structure GS2 (in detail, portions adjacent to the second channel layers 131) and the second source/drain patterns 150B. However, the first and second internal spacers 190A and 190B are formed by different methods and have different shapes.

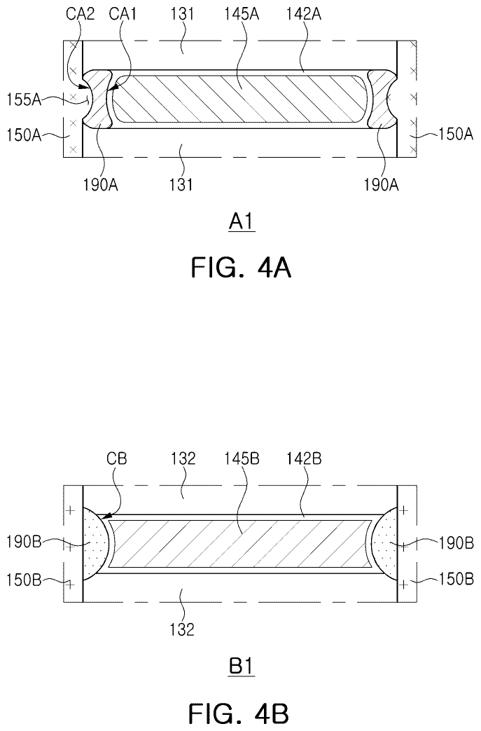

FIGS. 4A and 4B are partially enlarged views illustrating “A1” and “B1” of the semiconductor device of FIG. 2, respectively.

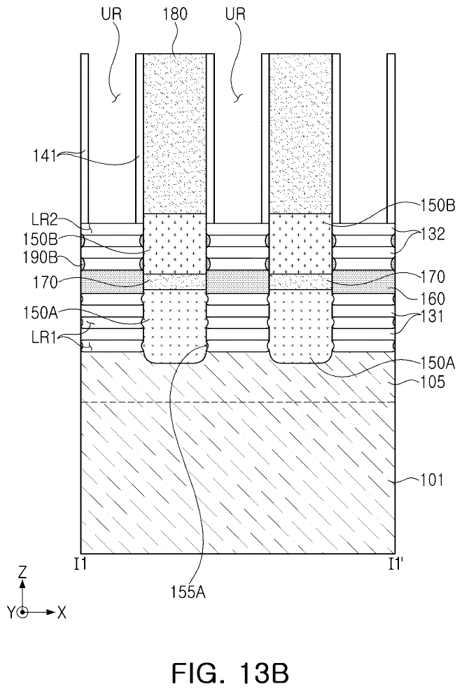

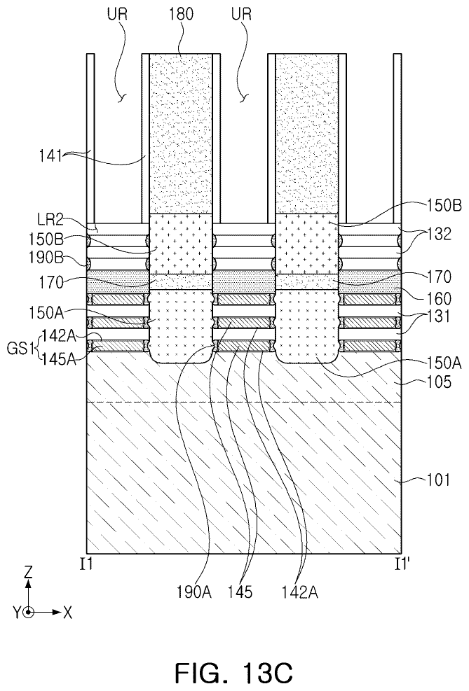

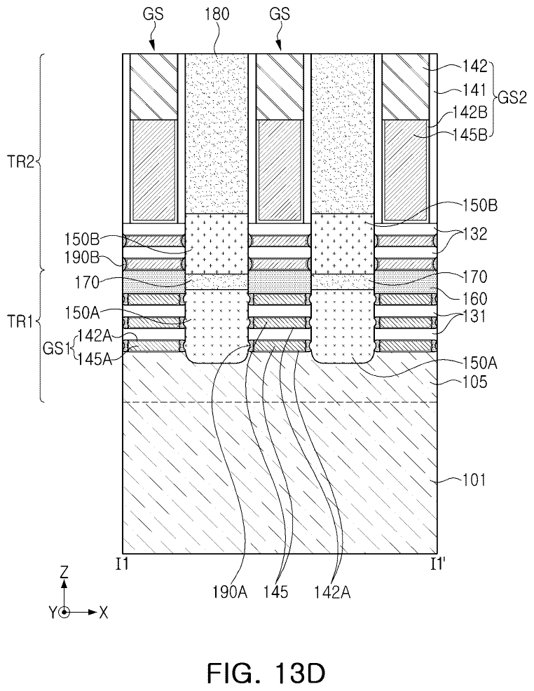

Referring to FIGS. 3 and 4A, each of the first internal spacers 190A may have side surfaces CA1 that are concave toward portions of the first gate structure GS1 adjacent to the first channel layers 131. In some embodiments, the side surfaces CA1 may have different shapes depending on the forming process of the first internal spacers 190A. For example, the side surfaces CA1 may have somewhat convex side surfaces. The first source/drain patterns 150A include indented portions 155A indented toward portions of the first gate structure GS1 adjacent to the first channel layers 131, and the indented portions 155A may overlap the first channel layers 131 in the vertical direction (for example, Z-direction). The side surface CA2 facing the indented portions 155A of each of the first internal spacers 190A may also have a concave side surface. These indented portions 155A may be provided as a buffer area to limit and/or prevent attack on the pre-formed first source/drain patterns 150A when the sacrificial layer 122 is removed in the process of forming the gate structure GS (see FIG. 13B).

Referring to FIGS. 3 and 4B, each of the second internal spacers 190B may have side surfaces CB convex toward portions of the second gate structure GS2 adjacent to the second channel layers 132, unlike the shape of the first internal spacers 190A.

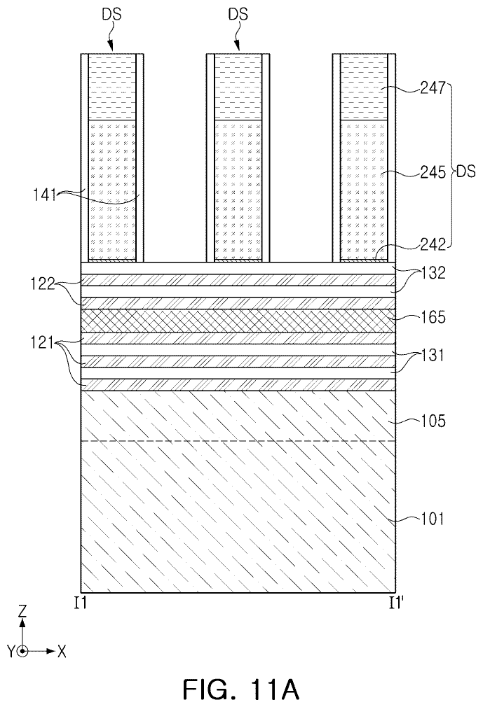

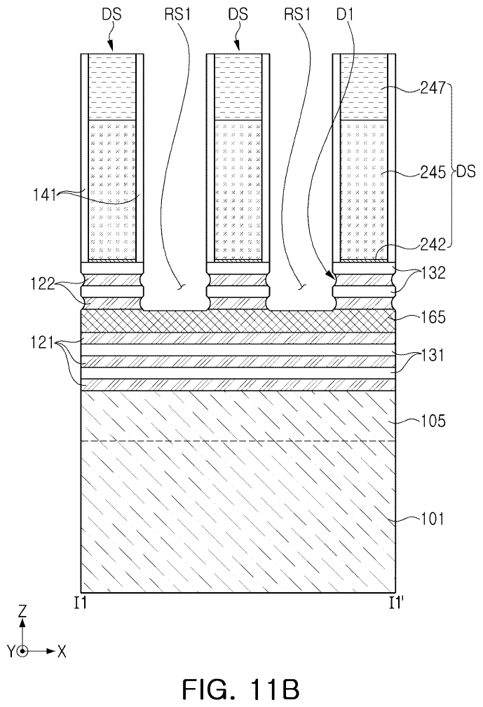

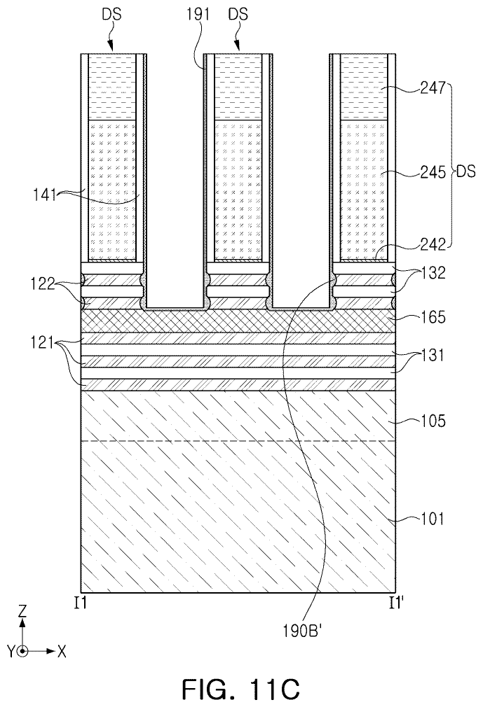

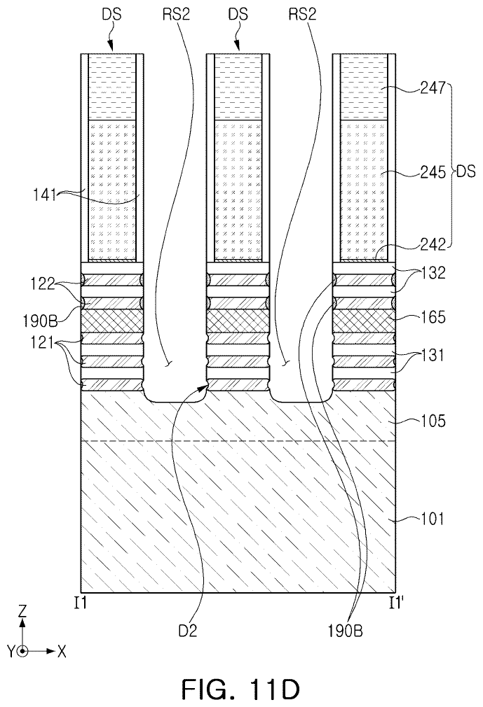

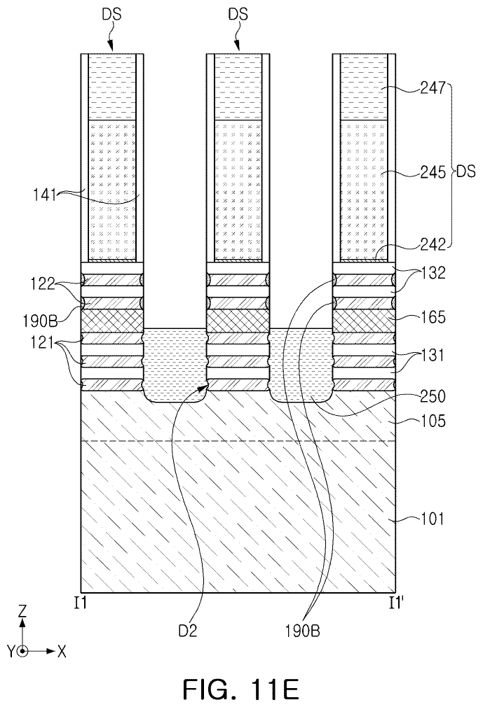

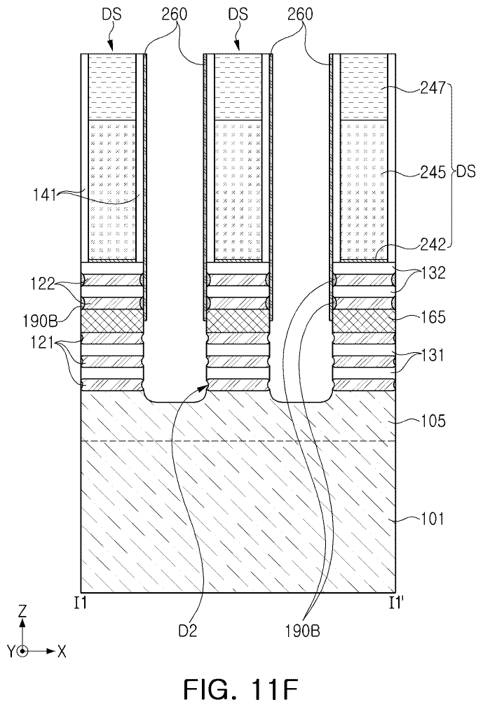

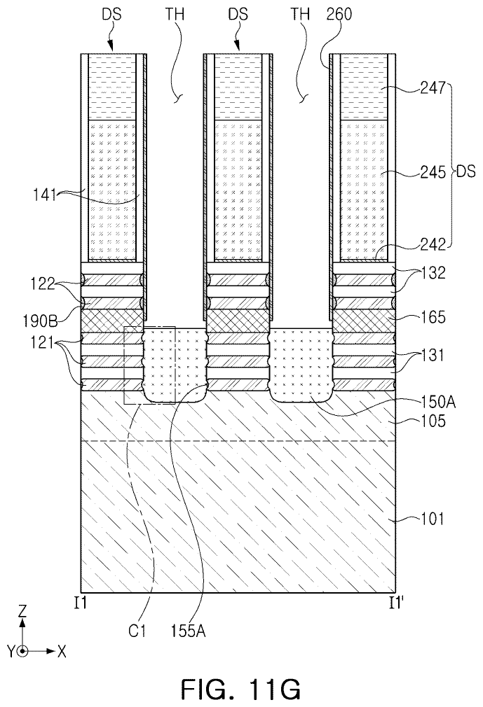

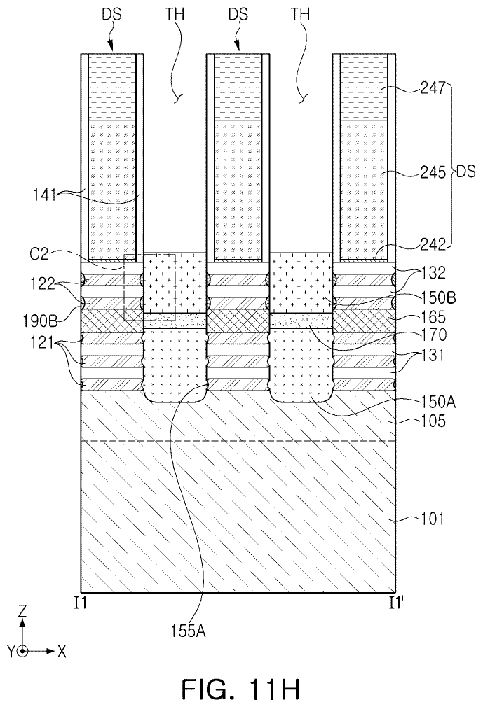

In the present embodiment, it may be understood that this structural difference results from a difference in the manufacturing process of the first and second internal spacers 190A and 190B. In detail, while the second internal spacers 190B are formed in advance (see FIG. 11E) after the recess process and before the formation of the second source/drain pattern 150B, the first internal spacers 190A are formed in the process of forming the first gate structure GS1 after forming the first source/drain pattern 150A (see FIG. 13C).

As such, in the present embodiment, the first source/drain patterns 150A may include SiGe epitaxial for applying compressive force to the first channel layers 131 as described above. However, if a crystal defect such as a dislocation occurs in the first source/drain pattern 150A, sufficient compressive force cannot be applied, unlike typical second internal spacers, the first internal spacers 190A are formed after forming the first source/drain pattern 150A, thereby significantly reducing crystal defects in the first source/drain pattern 150A.

As such, the first and second internal spacers 190A and 190B may have different shapes and structures due to differences in the above-described processes. This will be described in detail with reference to FIGS. 11A to 11H and 13A to 13D.

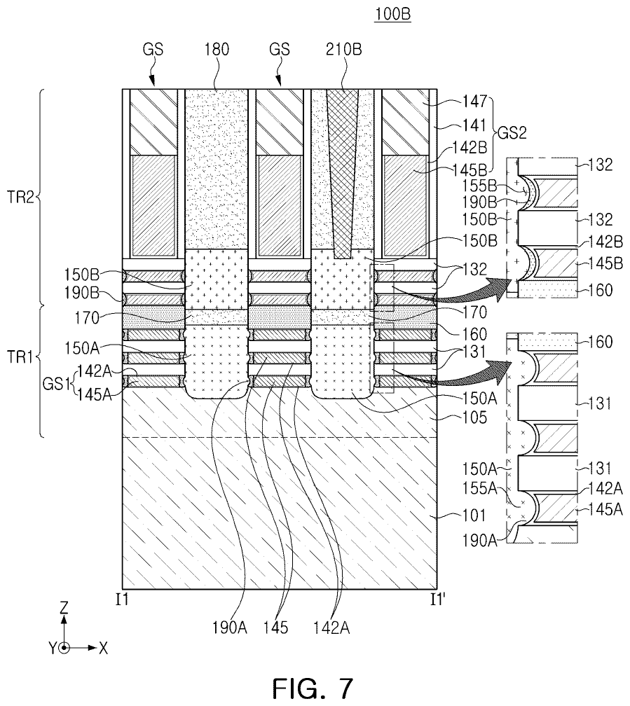

The second internal spacers 190B may extend to adjacent corner portions of adjacent second channel layers 132, as illustrated in FIG. 4B. In the present embodiment, the other side surface of the second internal spacers 190B (the side surface facing the second source/drain pattern 150B) is illustrated as a relatively flat side surface, but in some embodiments, even if the indentation depth or shape is different, similar to the first source/drain pattern 150A, the second source/drain pattern 150B may also have an indented portion (see ‘155B’ in FIG. 7) toward the second internal spacer 190B.

The semiconductor device 100 according to the present embodiment may include an interlayer insulating layer 180 disposed on the isolating insulation layer 170 and covering the second source/drain patterns 150B. The interlayer insulating layer 180 may be silicon oxide. For example, the interlayer insulating layer 180 may be Spin-on Hardmask (SOH), Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. The interlayer insulating layer 180 may be formed using a chemical vapor deposition (CVD), flowable-CVD process, or spin coating process.

The semiconductor device 100 according to the present embodiment may further include a first lower contact 210A connected to the first source/drain pattern 150A, first upper contacts 210B each connected to the second source/drain patterns 150B, and a second contact 220 connected to the second gate electrode 145B. The first upper contacts 210B are respectively connected to the second source/drain patterns 150B through the interlayer insulating layer 180, and the second contact 220 may penetrate the gate capping layer 147 and be connected to the second gate electrode 145B. The first lower contact 210A may include a horizontal contact portion 210L connected to the first source/drain pattern 150A and extending in a horizontal direction (for example, Y-direction) with the upper surface of the substrate 101, and a vertical contact portion 210V connected to the horizontal contact portion 210L and extending in a direction perpendicular to the upper surface of the substrate 101 (for example, Z-direction). For example, the contacts 210A, 210B, and 220 described above may include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (aL), Cobalt (Co), ruthenium (Ru), and molybdenum (Mo).

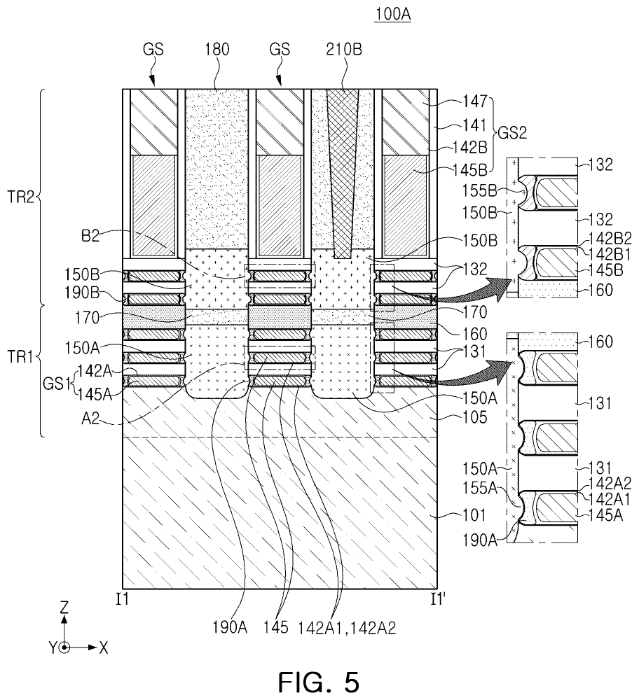

FIG. 5 is a cross-sectional view illustrating a semiconductor device according to an example embodiment, and FIGS. 6A and 6B are partially enlarged views illustrating “A2” and “B2” of the semiconductor device of FIG. 5, respectively.

Referring to FIGS. 5, 6A, and 6B, the semiconductor device 100A according to the present embodiment may be understood to be the same or similar to the semiconductor device 100 illustrated in FIGS. 1 to 4B, except that similar to the first internal spacers 190A, the second internal spacers 190B also have a concave side surface CA2 in contact with the second gate structure GS2, the second source/drain pattern 150B has an indented portion 155B similarly to the first source/drain pattern 150A, and the first and second gate insulating layers 142A and 142B include interface insulating films 142A1 and 142B1 and high-κ dielectric films 142A2 and 142B2. Additionally, unless otherwise stated, the components of the present embodiment may be understood with reference to descriptions of the same or similar components of the semiconductor device 100 illustrated in FIGS. 1 to 4B.

Referring to FIGS. 5 and 6A, similar to the previous embodiment, each of the first internal spacers 190A may have side surfaces CA1 that are concave toward portions of the first gate structure GS1 adjacent to the first channel layers 131. The first source/drain patterns 150A include indented portions 155A indented toward portions of the first gate structure GS1 adjacent to the first channel layers 131, and the indented portions 155A may overlap the first channel layers 131 in the vertical direction (for example, Z-direction). The side surface CA2 facing the indented portions 155A of each of the first internal spacers 190A may also have a concave side surface.

Referring to FIGS. 5 and 6B, each of the second internal spacers 190B employed in the present embodiment may have side surfaces CB1 concave toward portions of the second gate structure GS2 adjacent to the second channel layers 132, similar to the first internal spacers 190A. The second source/drain patterns 150B include indented portions 155B indented toward portions of the second gate structure GS2 adjacent to the second channel layers 132, and the indented portions 155B may overlap the second channel layers 132 in the vertical direction (for example, Z-direction). The side surface CB2 facing the indented portions 155B of each of the second internal spacers 190B may also have a concave side surface.

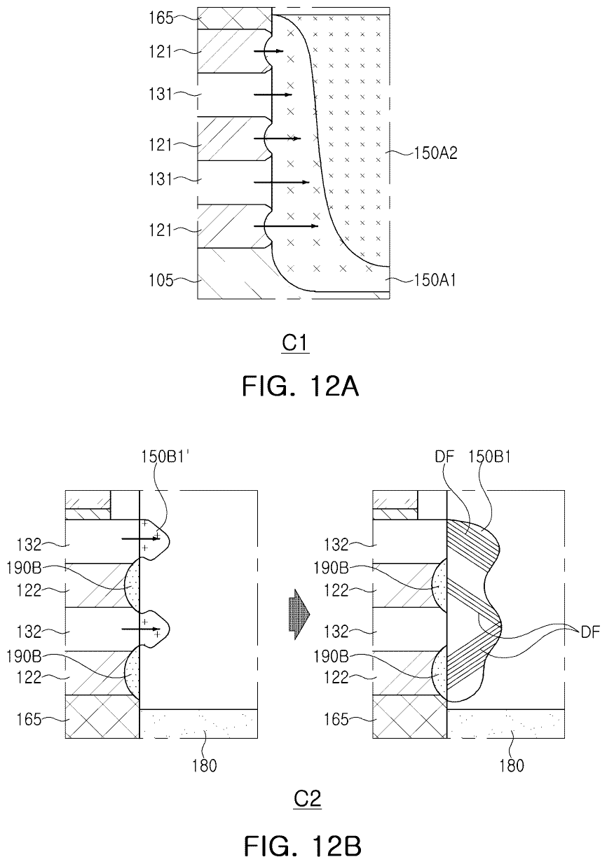

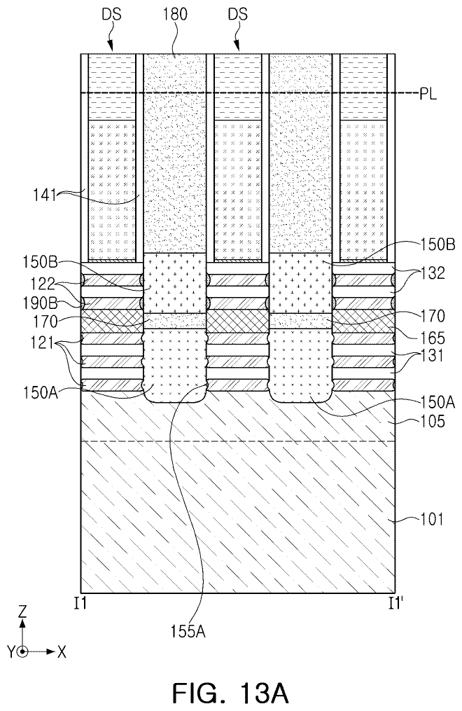

As such, the first and second internal spacers 190A and 190B are manufactured through a similar manufacturing process and are provided after forming the first and second source/drain patterns 150A and 150B. Therefore, in the epitaxial layers of the first and second source/drain patterns 150A and 150B, the side surfaces of the recess may be stably grown from all epitaxial crystal planes (for example, the first and second channel layers 131 and 132 and the sacrificial layers 122) (see FIGS. 11G and 12A).

Additionally, the indented portions 155A and 155B of the first and second source/drain patterns 150A and 150B may be provided as a buffer area to limit and/or prevent attack on the pre-formed first and second source/drain patterns 150A and 150B, when removing the sacrificial layer 122 in the process of forming the first and second gate structures GS1 and GS2 (see FIG. 13B).

However, since the first and second internal spacers 190A and 190B are formed through different processes, the detailed structures may have different shapes (for example, widths Wa and Wb and indented depths da and db).

First, the first internal spacers 190A and the second internal spacers 190A may have different widths (Wa≠Wb). For example, the first internal spacers 190A may have a width (Wa) greater than the width (Wb) of the second internal spacers 190A.

Similarly, the indented portions 155A and 155B of the first and second source/drain patterns 150A and 150B may have different depths (da≠db). For example, the indented portion 155A of the first source/drain pattern 150A may have a width da smaller than the depth db of the indented portion 155B of the second source/drain pattern 150B.

In the present embodiment, the first and second gate insulating layers 142A and 142B may include first and second interface insulating films 142A1 and 142B1 and first and second high-κ dielectric films 142A2 and 142B2, respectively. In some embodiments, the first and second internal spacers 190A and 190B may be respectively formed after forming the first and second interface insulating films 142A1 and 142B1 and before forming the first and second high-κ dielectric films 142A2 and 142B2.

As a result, as illustrated in FIG. 6A, each of the first internal spacers 190A may be disposed between the first interface insulating films 142A1 and the first high-κ dielectric film 142A2. Similarly, referring to FIG. 6B, each of the second internal spacers 190B may be disposed between the second interface insulating films 142B1 and the second high-κ dielectric film 142B2.

In some embodiments, the first and second interface insulating films 142A1 and 142B1 and the first and second internal spacers 190A and 190B may be formed of different materials. For example, the first and second interface insulating films 142A1 and 142B1 may include silicon oxide, and the first and second internal spacers 190A and 190B may include silicon nitride. In this case, the first and second interface insulating films 142A1 and 142B1 may include first portions in contact with the first and second channel layers, respectively, and second portions in contact with the first and second internal spacers 190A and 190B, and the first portions and second portions may include different materials. For example, the first portion may remain silicon oxide, while the second portion may be silicon oxynitride by nitrogen diffusion.

In contrast, similar to the previous embodiment, when the second internal spacers are introduced before forming the second source/drain pattern, the second internal spacers may be disposed between the second source/drain patterns and the second interface insulating film (see FIG. 10B).

FIG. 7 is a cross-sectional view illustrating a semiconductor device according to an example embodiment, and may be understood as a cross-section corresponding to FIG. 2.

Referring to FIG. 7, the semiconductor device 100B according to the present embodiment may be understood as the same as or similar to the semiconductor device 100 illustrated in FIGS. 1 to 4B, except that the internal spacers 190B are disposed only in the second transistor TR2 and not in the first transistor TR1, and the second source/drain pattern 150B also has an indented portion 155B similar to the first source/drain pattern 150A. Additionally, unless otherwise stated, the components of the present embodiment may be understood with reference to descriptions of the same or similar components of the semiconductor device 100 illustrated in FIGS. 1 to 4B.

In the present embodiment, the second transistor TR2 includes internal spacers 190B having convex side surfaces facing the portion of the second gate structure GS2 adjacent to the second channel layers 132, similar to the second internal spacer of the previous embodiment (see FIG. 2). The internal spacers 190B may be formed before forming the second source/drain patterns 150B. However, unlike the previous embodiment (see FIG. 2), the second source/drain patterns 150B include indented portions 155B that are indented toward portions of the second gate structure GS2 adjacent to the second channel layers 132. These indented portions 155B may overlap the second channel layers 132 in the vertical direction. The indented portions 155B may be formed by overetching in the process of partially removing the insulating film for forming the internal spacers 190B (see FIGS. 11C and 11D).

In the present embodiment, the first transistor TR1 may include first source/drain patterns 150A with indented portions and without internal spacers. The indented portions 155A of the first source/drain patterns 150A may be formed toward portions of the first gate structure GS1 adjacent to the first channel layers 131. In the present embodiment, the first source/drain patterns 150A may include silicon germanium (SiGe), and the second source/drain patterns 150B may include silicon (Si). In detail, the indented portions 155A of the first transistor TR1 may protect pre-formed first source/drain patterns 150A when removing the sacrificial layer 122 in the process of forming the first gate structure GS1 (see FIG. 13B). Accordingly, the first source/drain pattern 150A may stably apply compressive force to the first channel layers 131, thereby improving the mobility of the first channel layers 131.

In the present embodiment, each of the first source/drain patterns 150A may include a first epitaxial layer connected to each of the side surfaces of the first channel layers 131, and a second epitaxial layer on the first epitaxial layer, and the Ge concentration of the first epitaxial layer may be configured to be lower than the Ge concentration of the second epitaxial layer (see FIG. 12A). Accordingly, during the removal process of the sacrificial layer 122, the indented portion 155A may have a sufficient selectivity to function as a sufficient buffer area.

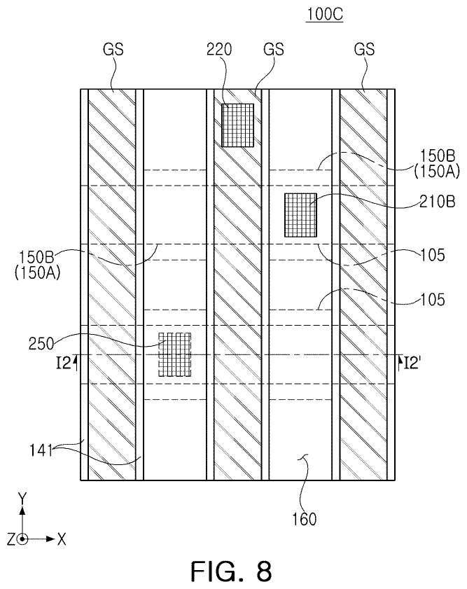

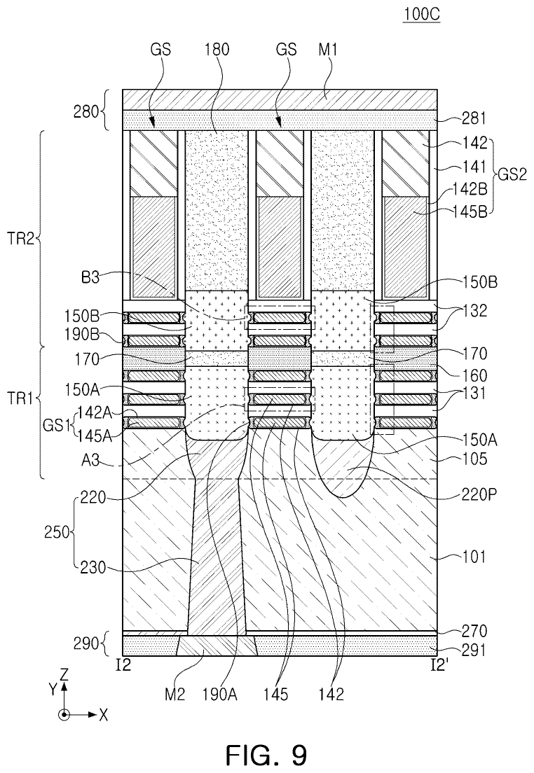

FIG. 8 is a plan view illustrating a semiconductor device according to an example embodiment, FIG. 9 is a cross-sectional view of the semiconductor device of FIG. 8 taken along line I2-I2′, and FIGS. 10A and 10B are partially enlarged views illustrating “A3” and “B3” of the semiconductor device of FIG. 9, respectively.

Referring to FIGS. 8, 9, 10A, and 10B, the semiconductor device 100C according to the present embodiment may be understood as the same as or similar to the semiconductor device 100 illustrated in FIGS. 1 to 4B, except that the second internal spacer 190B has first and second spacer portions 190B1 and 190B2 of different structures, the second internal spacer 190B has a concave side surface in contact with the second gate structure GS2, the first and second gate insulating layers 142A and 142B include first and second interface insulating films 142A1 and 142B1 and first and second high-κ dielectric films 142A2 and 142B2, respectively, other types of contact structures 220 and 230 are included, and the associated first and second interconnection structures 280 and 290 are both illustrated. Additionally, unless otherwise stated, the components of the present embodiment may be understood with reference to descriptions of the same or similar components of the semiconductor device 100 illustrated in FIGS. 1 to 4B.

In the present embodiment, the first internal spacer has a same or similar structure to the previous embodiments (see FIGS. 4A and 6A). On the other hand, the second internal spacer 190B, unlike the previous embodiments, has a first spacer portion 190B1 in contact with the second source/drain patterns 150B and a second spacer portion 190B2 in contact with the second gate structure GS2. The first spacer portion 190B1 has a convex side surface CB2 facing the second spacer portion 190B2, and the second spacer portion 190B2 has a concave side surface CB1 contacting the second gate structure GS2.

In the present embodiment, the first and second gate insulating layers 142A and 142B may include first and second interface insulating films 142A1 and 142B1 and first and second high-κ dielectric films 142A2 and 142B2, respectively. Referring to FIG. 10A, each of the first internal spacers 190A may be disposed between the first interface insulating films 142A1 and the first high-κ dielectric film 142A2, similar to the shape illustrated in FIG. 6A. On the other hand, referring to FIG. 10B, the first spacer portion 190B1 is disposed between the second source/drain patterns 150B and the second interface insulating film 141A2, and the second spacer portion 190B2 may be disposed between the second interface insulating film 141A2 and the second high-κ dielectric film 141B2.

The first source/drain patterns 150A include indented portions 155A indented toward the first internal spacers 190A, and the side surface CA2 facing the indented portions 155A of each of the first internal spacers 190A may also have a concave side surface. The second source/drain patterns 150B include indented portions 155B toward the second internal spacers 190B, and the side surface CB2 of each of the first spacer portions 190B1 facing the indented portions 155B may also have a concave side surface.

The semiconductor device 100C according to the present embodiment may include a first interconnection structure 280 (also referred to as a “front interconnection structure”) disposed on the interlayer insulating layer 180, and second interconnection structures 290 (also referred to as “back interconnection structures”) disposed on the lower surface of the substrate 101. The first interconnection structure 280 includes a first interconnection insulating layer 281 disposed on the interlayer insulating layer 180 and a first interconnection line M1 disposed in the first interconnection insulating layer 281. The first interconnection line M1 may be connected to the upper contact 210B or the second contact 220 through a metal via.

Similarly, the second interconnection structure 290 includes a second interconnection insulating layer 291 disposed on the lower surface of the substrate 101 and a second interconnection line M2 disposed in the second interconnection insulating layer 291. The second interconnection line M2 may be a power supply line. In the present embodiment, the etch stop layer 270 may be disposed between the substrate 101 and the second interconnection insulating layer 291. The etch stop film 270 may be used in a process of forming the second interconnection line M2.

The lower contact structure 250 employed in the present embodiment may penetrate the substrate 101 and connect the first source/drain pattern 150A to the second interconnection line M2. The lower contact structure 250 may include a conductive via 230 penetrating the substrate 101 and a conductive connection portion 220 obtained by selectively removing the buried insulating portion 220P. The buried insulating portion 220P may remain below the first source/drain pattern 150A where the lower contact structure 250 is not formed. The buried insulating portion 220P for forming the lower contact structure may be an obstacle to growing the epitaxial for the first source/drain pattern 150A, and in this structure, the method for improving crystallinity (introducing the indented portion 155A and/or the first internal spacer 190A) according to the present embodiment may be used more advantageously.

Hereinafter, a method for manufacturing a semiconductor device according to an example embodiment will be described.

FIGS. 11A to 11H and FIGS. 13A to 13D are cross-sectional views of each main process illustrating a method of manufacturing a semiconductor device according to an example embodiment. The manufacturing method according to the present embodiment is a manufacturing method of the semiconductor device 100 illustrated in FIGS. 1 to 3B, and each cross section may be understood as the corresponding drawing in FIG. 2.

In detail, FIGS. 11A to 11H are cross-sectional views of each main process for describing the formation process of first and second source/drain patterns as part of the semiconductor device manufacturing method according to an example embodiment, and FIGS. 13A to 13D are cross-sectional views of major processes for describing the formation process of first and second gate structures as another part of the semiconductor device manufacturing method according to an example embodiment.

First, referring to FIG. 11A, a fin-type stack structure is disposed on the active pattern 105 extending in a first direction (for example, X-direction) on the substrate 101, and a dummy gate structure (DS) in a second direction (for example, Y-direction) to intersect the fin-type stack structure may be included.

Each fin-type stack structure may include a first stack structure in which first sacrificial layers 121 and first channel layers 131 are alternately stacked, a second stack structure in which second sacrificial layers 122 and second channel layers 132 are alternately stacked on the first stack structure, and an intermediate sacrificial layer 165 between the first and second layered structures. The first channel layer 131 and the second channel layer 132 may include a semiconductor material to form channels for the first and second transistors. Each of the first channel layer 131 and the second channel layer 132 may include, for example, a semiconductor material including at least one of silicon (Si), silicon germanium (SiGe), and germanium (Ge). The first channel layer 131 and the second channel layer 132 may include impurities, but are not limited thereto. The intermediate insulating layer 160L may include at least one of SiO, SiN, SiCN, SiOC, SiON, SiOCN, SiBN, and SiBCN.

The first and second sacrificial layers 121 and 122 may include different materials to have etch selectivity with respect to the first and second channel layers 131 and 132. In some embodiments (for example, when the first and second gate electrodes are formed from different gate electrode materials), the first sacrificial layer 121 may include a different material from the second sacrificial layers 122 to have etch selectivity. For example, the first and second sacrificial layers 121 and 122 may include silicon germanium (SiGe), and the first and second channel layers 131 and 132 may include silicon (Si). In some embodiments, the number of layers of the first and second sacrificial layers 121 and 122 and the first and second channel layers 131 and 132 alternately stacked may vary.

Dummy gate structures DS and gate spacers 141 may be formed on the fin-type stack structure. Each of the dummy gate structures DS may be a sacrificial structure that provides space for forming gate structures GS to be formed in a subsequent process. The dummy gate structures DS have a line shape that intersects the fin-type stack structures and extends in the second direction (for example, Y-direction), and may be arranged to be spaced apart from each other in the first direction (for example, X-direction).

The dummy gate structures DS may include first and second dummy material layers 242 and 245 and a mask pattern layer 247 that are sequentially stacked. The first and second dummy material layers 242 and 245 may be patterned using the mask pattern layer 247. The first and second dummy material layers 242 and 245 may be an insulating layer and a conductive layer, respectively, but are not limited thereto, and the first and second dummy material layers 242 and 245 may be formed as one layer. In some embodiments, the first dummy material layer 242 may include silicon oxide, and the second dummy material layer 245 may include polysilicon. The mask pattern layer 247 may include silicon oxide and/or silicon nitride.

Gate spacers 141 may be formed on both sidewalls of the dummy gate structures DS. The gate spacers 141 may be formed by forming a film of uniform thickness along the upper and side surfaces of the substrate on which the dummy gate structures DS are formed and then anisotropically etching the film. The gate spacers 141 may be formed of a low dielectric constant material and may include, for example, at least one of SiO, SiN, SiCN, SiOC, SiON, and SiOCN.

Next, referring to FIG. 11B, the first recess RS1 may be formed by partially removing portions of the fin-type stack structure between the dummy gate structures DS up to the active pattern 105.

In this process, the first recess RS1 may be formed so that the intermediate sacrificial layer 165 is exposed in the exposed area of the fin-type stack structure using the dummy gate structures DS and gate spacers 141 as a mask. Through this process, the second channel layers 132 are etched with the second sacrificial layers 122 and may have a required length along the first direction (for example, X-direction). The first recess RS1 is provided as an area for forming a first source/drain pattern, and the second channel layers 132 and the second sacrificial layers 122 are formed by the first recess RS1. side surfaces may be exposed. The indented region D1 may be formed by additionally etching both ends of the second sacrificial layers 122 during the process of forming the first recess RS1 or through a separate additional process. The indented area D1 may define an area forming the second internal spacer. Since the surface of the indented portion during the etching process has a convex surface, the second internal spacers 190B formed in the area may also have a convex side surface.

Next, referring to FIG. 11C, a spacer insulating layer 191 is formed on the surface exposed by the first recess RS1 to fill the recessed area D1 of the second sacrificial layers 122.

The spacer insulating layer 191 may be formed conformally on the exposed surface. In detail, the spacer insulating layer 191 may be filled in the recessed area. The spacer insulating layer 191 may include silicon oxide (SiO₂), silicon nitride (SiN), silicon oxynitride (SiON), or silicon carbonitride (SiCN).

Next, referring to FIG. 11D, the second internal spacer 190B is formed using an etching process, and the first channel layers 131 and first sacrificial layers 121 are additionally selectively removed, thereby forming a second recess (RS2).

The second internal spacer 190B may be formed by removing the side walls of the second channel layers 132 and portions of the spacer insulating layer 191 located on the bottom surface of the first recess RS1. In this process, the exposed portion of the second internal spacer 190B may be additionally etched to have an indented structure (see FIG. 7). This etching process may be performed by an anisotropic etching process such as dry etching.

In addition, the first channel layers 131 and the first sacrificial layers 121, along with the intermediate sacrificial layer 165, are partially etched using the dummy gate structures DS and the gate spacers 141 as masks, thereby forming a second recess RS2. The side surfaces of the first channel layers 131 and the first sacrificial layers 121 may be exposed along with the bottom surface of the active pattern 105 by the second recess RS2.

The indented region D2 may be formed by additionally etching both ends of the first sacrificial layers 121 during the process of forming the second recess RS2 or through a separate additional process. The recessed area D2 may provide space for the indented portion 155A of the first source/drain patterns 150A illustrated in FIGS. 2 and 3A.

Next, referring to FIG. 11E, the second recess RS2 is filled with a gap-fill insulating material, and the gap-fill insulating material is etch-backed. A gap-fill insulating pattern 250 corresponding to the first source/drain pattern may be formed in each second recess RS2.

A gap-fill insulating material may be deposited to fill the spaces between the dummy gate structures DS. For example, the gapfill insulating material may be silicon oxide, such as spin on hardmask (SOH). A gap-fill insulating pattern 250 having a required height may be formed from the gap-fill insulating material deposited through an etch-back process. The gap-fill insulating pattern 250 may be formed to have an upper surface level that covers at least the side surfaces of the first channel layers 131. In the present embodiment, the upper surface level of the gap fill insulating pattern 250 may be formed to overlap the intermediate sacrificial layer 165 in the horizontal direction.

Next, referring to FIG. 11F, a blocking insulating layer 260 is formed on the exposed side wall portions of the dummy gate structure DS, and the gap fill insulating pattern 250 may be removed to open an area where the first source/drain pattern will be formed.

The side wall mask layer 260 forms a blocking insulating material conformally over the entire area. In detail, the blocking insulating material film is formed not only on the side walls of the dummy gate structures DS, but also on the upper surfaces of the dummy gate structures DS and the bottom surface therebetween (for example, the upper surface of the gap fill insulating pattern 250). The blocking insulating material layer may include a dielectric material that inhibits epitaxial growth. For example, it may include silicon nitride (SiN), silicon oxynitride (SiON), or silicon carbonitride (SiCN). Then, an anisotropic etching process such as dry etching is applied to remove portions located on the upper surface of the dummy gate structures DS and the gap fill insulating pattern 250 from the blocking insulating material film, and as illustrated in FIG. 11F, the blocking insulating layer 260 may remain on exposed side wall portions of the dummy gate structure DS. The blocking insulating layer 260 may be provided to cover a side wall portion of the dummy gate structure DS including the side surfaces of the second channel layers 132.

Next, the gap fill insulating pattern 250 may be removed to open the area where the first source/drain pattern will be formed. For example, the bottom portion of the active pattern 105 and the side surfaces of the first channel layers 131 may be exposed.

Next, referring to FIG. 11G, a process of forming the first source/drain pattern 150A may be performed.

First source/drain patterns 150A may be formed by growing epitaxially from the side surfaces of the first channel layers 131 in the second recess RS2. On the other hand, epitaxial layer growth may be suppressed in the area where the blocking insulating layer 260 is formed. In the present embodiment, the lower end of the blocking insulating layer 260 may be somewhat spaced apart from the first source/drain pattern 150A. A portion of the isolation insulation layer 170 may be located in the spaced-apart area in a subsequent process.

In the present embodiment, each of the first source/drain patterns 150A may include a first epitaxial layer 150A1 connected to each of the side surfaces of the first channel layers 131 and a second epitaxial layer 150A2 on the first epitaxial layer 150A1, and the Ge concentration of the first epitaxial layer 150A1 may be configured to be lower than the Ge concentration of the second epitaxial layer 150A2.

Referring to FIG. 12A, in this process, the side surfaces of the first sacrificial layers 121 serve as the epitaxial growth surface of the first source/drain pattern 150A together with the side surfaces of the first channel layers 131. Therefore, the first epitaxial layer 150A1 may grow relatively high-quality crystals from the side surfaces of the first sacrificial layers 121 and the first channel layers 131.

Additionally, the first epitaxial layer 150A1 may be grown in the recessed area D2 of the first sacrificial layer 121 to form the indented portion 155A of the first source/drain patterns 150A. This indented portion 155A may sufficiently function as a buffer area when the first sacrificial layer 121 is later removed (see FIG. 13B).

Next, referring to FIG. 11H, after removing the blocking insulating layer 260, an isolating insulation layer 170 is formed to cover the surface of the first source/drain patterns 150A, and subsequently, a second source/drain pattern 150B is formed.

Second source/drain patterns 150B may be formed by growing epitaxially from the side surfaces of the second channel layers 132 in the first recess RS1. In this process, unlike the epitaxial growth of the first source/drain patterns 150B, the second internal spacer 190B is formed on the side surface of the second sacrificial layers 122, and as illustrated in FIG. 12B, the epitaxial of the second source/drain pattern 150B is grown only on the side surfaces of the second channel layers 132, and portions grown on the side surfaces of the second channel layers 132 are merged on the second internal spacer 190B, thereby forming a required second source/drain pattern 150B. During this merging process, defects such as dislocations may occur significantly.

In contrast, since the first source/drain pattern 150A is surface-grown from the side surfaces of the first sacrificial layers 121 and the first channel layers 131 before forming the internal spacer, as described in FIG. 12A, relatively high quality crystals may be obtained without many crystal defects. Accordingly, the first source/drain pattern 150A may be configured to apply sufficient compressive force to improve the mobility of the first channel layer.

FIGS. 13A to 13D are cross-sectional views of each main process for describing another part (formation of first and second gate structures) of the semiconductor device manufacturing method according to an example embodiment.

Referring to FIG. 13A, an interlayer insulating layer 190 is formed, and a polishing process is performed at a constant level PL to expose the second dummy material layer 245. Next, referring to FIG. 13B, the first and second dummy material layers 242 and 245 and the first and second sacrificial layers 121 and 122 are removed, thereby forming upper gap regions UR and first and second lower gap regions LR1 and LR2 may be formed.

In some embodiments, after removing the first and second dummy material layers 242 and 245, the intermediate sacrificial layer 165 may be removed first, and the intermediate insulating pattern 160 may be formed. Selective removal of the intermediate sacrificial layer 165 may be implemented by configuring the Ge concentration to be higher than that of the first and second sacrificial layers 121 and 122.

Next, the first and second sacrificial layers 121 and 122 may be removed to form first and second lower gap regions LR1 and LR2. In this process, the second source/drain patterns 150B are protected by the second internal spacer 190B, and in the first lower gap regions LR1, substantially the entire area may be protected by the indented portion 155A of the first source/drain patterns 150A. In detail, since the indented portion 155A is composed of the first epitaxial layer (150A1 in FIG. 12A) with a relatively low Ge concentration, during the process of removing the first sacrificial layer 121, substantial damage to the first source/drain patterns 150A may be limited and/or prevented. In the final structure, the indented portions 155A of the first source/drain patterns 150A are partially etched away, but some portions may remain. In some embodiments, the indented portions 155A of the first source/drain patterns 150A may be substantially removed.

Next, referring to FIG. 13C, first internal spacers 190A may be formed in the first lower gap regions LR1, and then the first gate structure GS1 may be formed.

The first internal spacers may be implemented by repeatedly performing a deposition process and an etching process. In detail, an insulating film is formed on the inner surface of the first lower gap regions LR1 using a deposition process such as an atomic layer deposition process. In the first lower gap regions LR1, the first film portion on both ends in the first direction (for example, X-direction) may be deposited to a thickness relatively greater than the thickness of the second film portion on the upper and lower surfaces of the first channel layer, and even if the relatively thin second film portion is removed during the etching process, the first film portion may remain. By repeating these deposition and etching processes, the required first internal spacer 190A may be formed. Through this process, each of the first internal spacers 190A may have side surfaces CA1 that are concave toward the center of the first lower gap regions LR1.

By forming a first gate insulating layer 142A surrounding the first channel layers 131 and forming a first gate electrode 145A on the first gate insulating layer 142A, a first gate structure GS1 may be formed to fill the first lower gap regions LR1.

Next, referring to FIG. 13D, the second gate structure GS2 may be formed in the second lower gap regions LR2 and the upper gap region UR.

By forming a second gate insulating layer 142B surrounding the second channel layers 132 and forming a second gate electrode 145B on the second gate insulating layer 142B, a second gate structure GS2 may be formed to fill the second lower gap regions LR2. In the second gate structure GS2, after filling the second gate insulating layer 142B and the second gate electrode 145B between the gate spacers 141 and partially etching back the second gate electrode 145B, a gate capping layer 147 may be formed. Next, the semiconductor device 100 illustrated in FIG. 2 may be manufactured by forming contact structures 210A, 210B, and 220.

As set forth above, at least a first transistor, unlike a second transistor located thereabove, has a first internal spacer introduced during a gate structure formation process after forming a first source/drain pattern. Therefore, crystallinity of the first source/drain pattern (for example, SiGe) may be improved, and as a result, force caused by the first source/drain pattern may be preserved by reducing defects.

On the other hand, in a process of manufacturing a first internal spacer, a structure (indentations) indented toward the gate structure of first source/drain patterns may be provided to reduce unwanted loss of the first source/drain patterns when removing a sacrificial layer (for example, SiGe).

While example embodiments have been illustrated and described above, it will be apparent to those skilled in the art that modifications and variations could be made without departing from the scope of inventive concepts as defined by the appended claims.

What is claimed is:

1. A semiconductor device comprising:
a substrate including an active pattern;
first channel layers spaced apart from each other on the active pattern in a vertical direction, the vertical direction being perpendicular to an upper surface of the substrate;
a first gate structure surrounding the first channel layers;
first source/drain patterns on both sides of the first gate structure and connected to the first channel layers;
first internal spacers between the first gate structure and the first source/drain patterns;
second channel layers spaced apart from each other in the vertical direction on the first channel layers;
a second gate structure on the first gate structure and surrounding the second channel layers;
second source/drain patterns on both sides of the second gate structure and connected to the second channel layers; and
second internal spacers between the second gate structure and the second source/drain patterns, a shape of the second internal spacers being different from a shape of the first internal spacers.

2. The semiconductor device of claim 1, wherein
the first source/drain patterns include silicon germanium (SiGe), and
the second source/drain patterns include silicon (Si).

3. The semiconductor device of claim 1, wherein
side surfaces of the first internal spacers are concave and face toward portions of the first gate structure.

4. The semiconductor device of claim 1, wherein
the first source/drain patterns include indented portions,
the indented portions of the first source/drain patterns are indented toward portions of the first gate structure, and
the indented portions of the first source/drain patterns overlap the first channel layers in the vertical direction.

5. The semiconductor device of claim 4, wherein
side surfaces of the first internal spacers face the indented portions of the first source/drain patterns and have a concave surface.

6. The semiconductor device of claim 1, wherein
side surfaces of the second internal spacers are convex toward portions of the second gate structure.

7. The semiconductor device of claim 1, wherein
the second source/drain patterns include indented portions,
the indented portions of the second source/drain patterns are indented toward portions of the second gate structure, and
the indented portions of the second source/drain patterns overlap the second channel layers in the vertical direction.

8. The semiconductor device of claim 7, wherein
side surfaces of the second internal spacers face the indented portions of the second source/drain patterns and have a concave side surface.

9. The semiconductor device of claim 1, wherein
the first gate structure includes a first gate electrode and a first gate insulating layer,
the first gate electrode surrounds the first channel layers,
the first gate insulating layer is between the first gate electrode and the first channel layers,
the first gate insulating layer includes a first interface insulating film and a first high-κ dielectric film on the first interface insulating film, and
the first internal spacers are between the first interface insulating film and the first high-κ dielectric film.

10. The semiconductor device of claim 1, wherein
the second gate structure includes a second gate electrode and a second gate insulating layer,
the second gate electrode surrounds the second channel layers,
the second gate insulating layer is between the second gate electrode and the second channel layers,
the second gate insulating layer includes a second interface insulating film and a second high-κ dielectric film on the second interface insulating film,
the second internal spacers are between the second source/drain patterns and the second interface insulating film,
a first portion of the second interface insulating film is on the second channel layers,
a second portion of the second interface insulating film is on the second internal spacers,
the first portion of the second interface insulating film and the second portion of the second interface insulating film include different materials.

11. The semiconductor device of claim 1, wherein
concave side surfaces of the first internal spacers face toward portions of the first gate structure,
concave side surfaces of the second internal spacers face toward portions of the second gate structure, and
widths of the first internal spacers are different than widths of the second internal spacers.

12. The semiconductor device of claim 11, wherein
the first source/drain patterns include indented portions,
the indented portions of the first source/drain patterns are indented toward portions of the first gate structure,
and the indented portions of the first source/drain patterns overlap the first channel layers in the vertical direction.

13. The semiconductor device of claim 12, wherein
the second source/drain patterns include indented portions,
the indented portions of the second source/drain patterns are indented toward portions of the second gate structure,
the indented portions of the second source/drain patterns overlap the second channel layers in the vertical direction, and
lengths of the indented portions of the first source/drain patterns are different from lengths of the indented portions of the second source/drain patterns.

14. A semiconductor device comprising:
a substrate including an active pattern;
first channel layers spaced apart from each other on the active pattern in a vertical direction, the vertical direction being perpendicular to an upper surface of the substrate;
a first gate structure surrounding the first channel layers;
first source/drain patterns on both sides of the first gate structure and connected to the first channel layers;
first internal spacers between the first gate structure and the first source/drain patterns, concave side surfaces of the first internal spacers being in contact with the first gate structure;
second channel layers spaced apart from each other in the vertical direction on the first channel layers;
a second gate structure surrounding the second channel layers on the first gate structure;
second source/drain patterns on both sides of the second gate structure and connected to the second channel layers; and
second internal spacers between the second gate structure and the second source/drain patterns, each of the second internal spacers including a first spacer portion in contact with the second source/drain patterns and a second spacer portion in contact with the second gate structure.

15. The semiconductor device of claim 14, wherein
a side surface of the first spacer portion has a convex shape and contacts the second spacer portion.

16. The semiconductor device of claim 14, wherein
the first gate structure respectively includes a first gate insulating layer and a first high-κ dielectric film,
the first gate insulating layer includes a first interface insulating film surrounding the first channel layers,
the first high-κ dielectric film is on the first interface insulating film, and
the first internal spacers are between the first interface insulating film and the first high-κ dielectric film.

17. The semiconductor device of claim 14, wherein
the second gate structures includes a second gate insulating layer and a second high-κ dielectric film,
the second gate insulating layer includes a second interface insulating film surrounding the second channel layers,
the second high-κ dielectric film is on the second interface insulating film, and
the second spacer portion is between the second interface insulating film and the second high-κ dielectric film.

18. A semiconductor device comprising:
a substrate including an active pattern;
first channel layers spaced apart from each other on the active pattern in a vertical direction, perpendicular to an upper surface of the substrate;
a first gate structure surrounding the first channel layers;
first source/drain patterns on both sides of the first gate structure, the first source/drain patterns being connected to the first channel layers, the first source/drain patterns including indented portions, and the indented portions of the first source/drain patterns being indented toward portions of the first gate structure;
second channel layers spaced apart from each other in the vertical direction on the first channel layers;
a second gate structure surrounding the second channel layers on the first gate structure;
second source/drain patterns on both sides of the second gate structure and connected to the second channel layers; and
internal spacers between the second gate structure and the second source/drain patterns.

19. The semiconductor device of claim 18, wherein
the first source/drain patterns include silicon germanium (SiGe), and
the second source/drain patterns include silicon (Si).

20. The semiconductor device of claim 19, wherein
the first source/drain patterns each include a first epitaxial layer connected to a side surface of a corresponding one of the first channel layers and a second epitaxial layer on the first epitaxial layer, and
a Ge concentration of the second epitaxial layer is higher than a Ge concentration of the first epitaxial layer.
